(19) United States
(12) Patent Application Publication
(10) Pub. No.: US 2016/0315040 A1
(43) Pub. Date: Oct. 27, 2016

(54) CORE FOR REVERSE REFLOW, SEMICONDUCTOR PACKAGE, AND METHOD OF FABRICATING SEMICONDUCTOR PACKAGE

(71) Applicant: MK Electron Co., Ltd., Gyeonggi-do (KR)

(72) Inventors: Jae Yeol SON, Gyeonggi-do (KR); Jeong Tak MOON, Gyeonggi-do (KR); Jae Hun SONG, Gyeonggi-do (KR); Young Woo LEE, Incheon (KR); Eung Jae KIM, Daegu (KR); Su-Yong RYU, Incheon (KR); Hui Joong KIM, Seoul (KR); Ho Gun CHA, Daejeon (KR); Ik Joo MAENG, Gyeonggi-do (KR); Chan Goo YOO, Gyeonggi-do (KR)

(73) Assignee: MK Electron Co., Ltd.

(21) Appl. No.: 15/134,848

(22) Filed: Apr. 21, 2016

(30) Foreign Application Priority Data
Apr. 23, 2015 (KR) 1020150057542
Sep. 24, 2015 (KR) 1020150135584

(51) Int. Cl. H01L 23/498; H01L 23/00; H01L 21/48

(52) U.S. Cl. CPC H01L 23/49816; H01L 21/4853; H01L 24/13; H01L 24/11; H01L 2224/13582; H01L 2224/13655; H01L 2224/13657; H01L 2224/13644; H01L 2224/13669; H01L 2224/13026; H01L 2224/13014; H01L 2224/11318; H01L 2224/11849; H01L 2924/014; H01L 2924/351

(57) ABSTRACT

Provided are a reverse-reflow core, a semiconductor package, and a method of fabricating a semiconductor package. The semiconductor package includes: a semiconductor apparatus including a bump pad; and a bump portion bonded to the bump pad. The bump portion includes: a core; an intermetallic compound layer formed on the core; and a solder layer coating the intermetallic compound layer, wherein the thickness of a portion of the solder layer decreases as the distance between the portion of the solder layer and the bump pad increases. The reverse-reflow core, the semiconductor package, and the method of fabricating a semiconductor package enable the fabrication of a semiconductor package having high bonding strength and a high degree of precision.

### RELATED APPLICATIONS

This application claims the benefit of Korean Patent Application Nos. 10-2015-0057542, filed on Apr. 23, 2015, and 10-2015-0135584, filed on Sep. 24, 2015, in the Korean Intellectual Property Office, the disclosures of which are incorporated herein in their entirety by reference.

### BACKGROUND OF THE INVENTION

1. Field of the Invention

One or more embodiments relate to a core for reverse reflow, a semiconductor package, and a method of fabricating the semiconductor package and, more particularly, to a core for reverse reflow, a semiconductor package, and a method of fabricating the semiconductor package, enabling the fabrication of a semiconductor package having a high degree of precision and high bonding strength.

2. Description of the Related Art

Printed circuit boards (PCBs) are widely used in household electronic appliances including televisions, mobile phones, and computers. Recently, the use of PCBs has extended to vehicles. As a solder that is used in household electronic appliances, tin (Sn)-lead (Pb) based alloy products are often used. In this regard, lead (Pb) is an element determining wettability, strength, and mechanical characteristics of an alloy to be formed, and due to the inclusion of lead (Pb), the melting point of the alloy may be lowered down to 183° C., and accordingly, thermal damage occurring when the solder is soldered with electronic components in the procedure of semiconductor processes may be prevented.

Meanwhile, in the backdrop that environmental problems associated with lead (Pb) are more stringently regulated, three elements-based, lead-free solder alloy of tin (Sn)-silver (Ag)-copper (Cu) has been suggested. For high-density mounting of three-dimensional packages, plating balls to be used are formed by plating metallic or non-metallic core with Ni, and forming a two elements-based plating layer including, for example, tin (Sn)-silver (Ag), or a three elements-based plating layer including, for example, tin (Sn)-silver (Ag)-copper (Cu), thereon to transfer electric signals of the packages. These plating balls show excellent stand-off characteristics, because in a reflow process, the core is not melted and only a plated solder layer is melted. However, the three elements-based solder plating layer is manufactured at high costs, and the solder layer has low quality stability and low bonding strength.

### SUMMARY OF THE INVENTION

One or more embodiments include a core for reverse reflow, which enables the fabrication of a semiconductor package having high bonding strength and a high degree of precision.

One or more embodiments include a semiconductor package that has a high degree of precision and high bonding strength.

One or more embodiments include a method of fabricating a semiconductor package having a high degree of precision.

One or more embodiments include an electronic system including a semiconductor package that has a high degree of precision and high bonding strength.

Additional aspects will be set forth in part in the description which follows and, in part, will be apparent from the description, or may be learned by practice of the presented embodiments.

According to one or more embodiments, a reverse-reflow core includes: a core; a first metal layer that coats the core; and a second metal layer that coats the first metal layer. In some embodiments, the first metal layer may include nickel (Ni) or cobalt (Co), and the second metal layer may include gold (Au) or platinum (Pt). In some embodiments, a thickness of the second metal layer may be in a range of about 0.01 μm to about 0.3 μm.

According to one or more embodiments, a semiconductor package includes: a semiconductor apparatus including a bump pad; and a bump portion bonded to the bump pad. Herein, the bump portion may include: a core; an intermetallic compound layer formed on the core; and a solder layer coating the intermetallic compound layer. In some embodiments, the thickness of a portion of the solder layer may decrease as the distance between the portion of the solder layer and the bump pad increases.

The solder layer may coat the intermetallic compound layer in such a manner that the solder layer completely surrounds the core. The intermetallic compound of the intermetallic compound layer may include at least one selected from NiCu₃Sn₄, (Cu,Ni)₆Sn₅, and Ni₃Sn₄. In some embodiments, the semiconductor package may further include a first metal layer between the core and the intermetallic compound layer.

In some embodiments, the semiconductor apparatus may be a semiconductor chip. In some embodiments, optionally, the semiconductor apparatus may include a package substrate, and a semiconductor chip disposed on the package substrate, and the bump pad may be provided on the package substrate. The solder layer may not substantially include an organic material.

In some embodiments, the thickness of the solder layer may be monotonically decreased away from the bump pad.

According to one or more embodiments, a method of fabricating a semiconductor package includes: providing a substrate with a bump pad thereon; dotting solder paste or reflowed solder bump on the bump pad; providing a reverse-reflow core on the solder paste or the reflowed solder bump; and reflowing the solder paste or the solder bump to form a solder layer on the reverse-reflow core, wherein the reverse-reflow core may include a gold (Au) or platinum (Pt) layer as a surface thereof.

In some embodiments, the gold (Au) or platinum (Pt) layer may have a thickness of about 0.1 μm to about 0.3 μm. The reflowing of the solder paste may be performed at a temperature of about 200° C. to about 300° C.

In some embodiments, the reverse-reflow core may be off-centered by 5 μm or less before and after the reflowing of the solder paste.

In the reflowing of the solder paste, the solder paste may be elevated along a surface of the reverse-reflow core in a direction opposite to a direction of gravity.

In some embodiments, a thickness of the solder layer may gradually decrease away from the substrate.

According to one or more embodiments, an electronic system includes: a controller; an input or output unit to input or output data; a memory unit to store the data; n interface unit to transmit data to an external apparatus; and a bus to connect the controller, the input/output unit, the memory unit, and the interface unit so that the controller, the input/output unit, the memory unit, and the interface unit communicate with each other. In some embodiments, at least one of the controller and the memory unit may include the semiconductor package.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view of a reverse-reflow core according to an embodiment;

FIG. 2 is a flowchart to explain a method of fabricating a semiconductor package according to an embodiment;

FIGS. 3A to 3D are side cross-sectional views to explain a method of fabricating a semiconductor package according to an embodiment;

FIG. 4 shows an enlarged view of portion IV of FIG. 3;

FIG. 5 shows a conceptual view of a semiconductor interconnect according to an embodiment;

FIG. 6 shows a side cross-sectional view of a semiconductor package according to an embodiment;

FIG. 7 is a cross-sectional perspective view of a reverse-reflow core according to another embodiment;

FIGS. 8A and 8B show side cross-sectional views of a semiconductor package including the reverse-reflow core illustrated in FIG. 7 according to another embodiment to explain a method of fabricating the semiconductor package;

FIGS. 9A and 9B show side cross-sectional views of various examples of a semiconductor interconnect;

FIG. 10 shows images of the results of Experimental Example 8 to Experimental Example 13;

FIG. 11 shows images of the results of Experimental Example 14 to Experimental Example 19.

FIG. 12 shows a graph of off-center displacement of samples of Experimental Examples 8 to 19 in a horizontal direction (X direction) and a vertical direction (Y direction), caused by reflow;

FIG. 13 shows images of an interfacial compound between the solder and the core samples of Experimental Examples 10, 11, 16, and 17 in which gold is coated on the core;

FIG. 14 is a plan view of a memory module including a semiconductor package according to an embodiment;

FIG. 15 is a schematic diagram of a memory card including a semiconductor package according to an embodiment;

FIG. 16 is a block diagram of a memory apparatus including a semiconductor package according to an embodiment of the present disclosure;

FIG. 17 is a block diagram of an electronic system including a semiconductor package, according to an embodiment of the present disclosure; and

FIG. 18 is a block diagram of a network system including a server system including a semiconductor package, according to an embodiment of the present disclosure.

### DETAILED DESCRIPTION OF THE PREFERRED EMBODIMENTS

The present disclosure will now be described more fully with reference to the accompanying drawings, in which exemplary embodiments of the present disclosure are shown. The present disclosure may, however, be embodied in many different forms by one of ordinary skill in the art without departing from the technical teaching of the present disclosure. In other words, particular structural and functional description of the present disclosure are provided in descriptive sense only; various changes in form and details may be made therein and thus should not be construed as being limited to the embodiments set forth herein. As the present disclosure is not limited to the embodiments described in the present description, and thus it should not be understood that the present disclosure includes every kind of variation examples or alternative equivalents included in the spirit and scope of the present disclosure.

In the present description, terms such as ‘first’, ‘second’, etc., are used to describe various elements. However, it is obvious that the elements should not be defined by these terms. The terms are used only for distinguishing one element from another element. For example, a first element may be termed a second element, and similarly, a second element may be termed a first element, without departing from the teaching of the present disclosure.

The terminology used herein is for the purpose of describing particular embodiments only and is not intended to be limiting of example embodiments. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items. Expressions such as “at least one of,” when preceding a list of elements, modify the entire list of elements and do not modify the individual elements of the list. As used herein, the term “and/or” includes any and all combinations of one or more of the associated listed items. Expressions such as “at least one of,” when preceding a list of elements, modify the entire list of elements and do not modify the individual elements of the list.

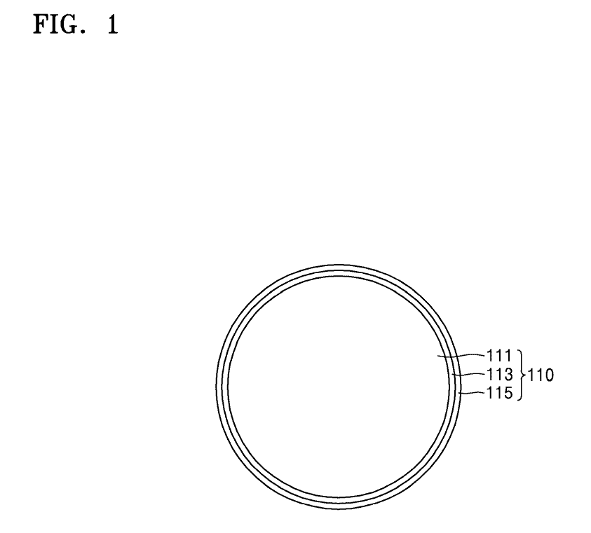

FIG. 1 is a schematic cross-sectional view of a reverse-reflow core 110 according to an embodiment.

Referring to FIG. 1, the reverse-reflow core 110 may include a core 111, a first metal layer 113 coating the core 111, and a second metal layer 115 coating the first metal layer 113.

The core 111 may include metal or an organic material in the art, an organic/organic composite, or an organic/inorganic composite.

In various embodiments, when the core 111 includes an organic material, the core 111 may include a plastic core including a thermosetting resin, such as an epoxy-based resin, a melamine-formaldehyde-based resin, a benzoguanamine-formaldehyde-based resin, a divinylbenzene resin, a divinylether resin, an oligo resin, a polydiacrylate resin, or an alkylenebisacrylamide resin, a plastic core including a thermoplastic resin, such as a polyvinylchloride resin, a polyethylene resin, a polystyrene resin, a nylon resin, or a polyacetal resin, or an elastic core, such as natural rubber or synthetic rubber. In various embodiments, the core 111 may include a plastic core including a mixed resin including the thermosetting resin and the thermoplastic resin.

When the core 111 includes an organic material, the core 111 may be formed by using a polymer synthesis method. In various embodiments, the core 111 may be formed by suspension, emulsification, or dispersion-polymerization, and may have a diameter of about 20 μm to about 300 μm.

When the core 111 includes metal, the core 111 may include, for example, pure copper (Cu), nickel (Ni), aluminum (Al), or an alloy thereof.

The core 111 illustrated in FIG. 1 may be spherical. However, the shape of the core 111 is not limited thereto. The core 111 may be, for example, cylindrical-shaped, rectangular pillar-shaped, a polygonal pillar-shaped, cone-shaped, or pyramid-shaped.

The first metal layer 113 may be provided on the core 111. The first metal layer 113 may be formed directly on the core 111; or an intervening material layer may be interposed between the core 111 and the metal layer 113.

Components consisting of the first metal layer 113 may be, for example, gold (Au), silver (Ag), nickel (Ni), zinc (Zn), tin (Sn), aluminum (Al), chromium (Cr), cobalt (Co), or antimony (Sb), but is not limited thereto. These materials may be used alone or in any combinations. In various embodiments, the first metal layer 113 may be formed by plating, physical vapor deposition, or chemical vapor deposition. When the first metal layer 113 is formed by plating, for example, nickel may be used by electroplating or electroless plating.

When the first metal layer 113 is formed, a brightener may be used to improve roughness of the surface of the first metal layer 113. That is, due to the use of the brightener, the first metal layer 113 may have a brightened surface. Non-limiting examples of the brightener include an oxygen-containing organic compound, for example, a polyether-based compound, such as polyethyleneglycol; a nitrogen-containing organic compound, such as a tertiary amine compound or a quaternary ammonium compound; and/or a sulfur-containing organic compound, such as a sulfonate group.

A thickness of the first metal layer 113 may be in a range of about 1 μm to about 5 μm. The first metal layer 113 may react with tin (Sn)-based solder paste to form, for example, an intermetallic compound, such as NiCu₃Sn₄, (Cu,Ni)₆Sn₅, or Ni₃Sn₄.

The second metal layer 115 may be further formed on the first metal layer 113.

The second metal layer 115 may have a thickness of about 0.01 μm to about 0.3 μm, or about 0.1 μm to about 0.2 μm. When the second metal layer 115 is too thin, a solder that has been subjected to reflowing may not completely cover the core for reverse reflow. When the second metal layer 115 is too thick, fabrication costs are high, and when subjected to reflowing, the second metal layer 115 may react with a tin (Sn)-based solder to form an intermetallic compound (IMC) having low strength, for example, AuSn₄.

The second metal layer 115 may include, for example, gold (Au), platinum (Pt), or an alloy thereof. The second metal layer 115 may be easily mixed with solder paste by heating. Since the second metal layer 115 includes metal that is hardly oxidized, the surface of the reverse-reflow core 110 may be suppressed from being oxidized due to the second metal layer 115.

The second metal layer 115 may be formed by, for example, electrolytic plating, electroless plating, physical vapor deposition, or chemical vapor deposition and so forth. However, a method for forming the second metal layer 115 is not limited thereto.

The reverse-reflow core 110 in itself is not used as a solder bump. The reverse-reflow core 110 may constitute a part of a semiconductor interconnect after being subjected to a reflow process together with solder paste. Explanations thereof will now be provided.

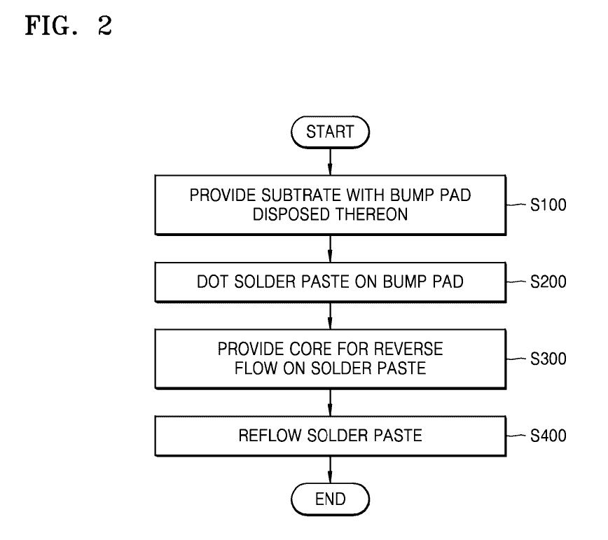

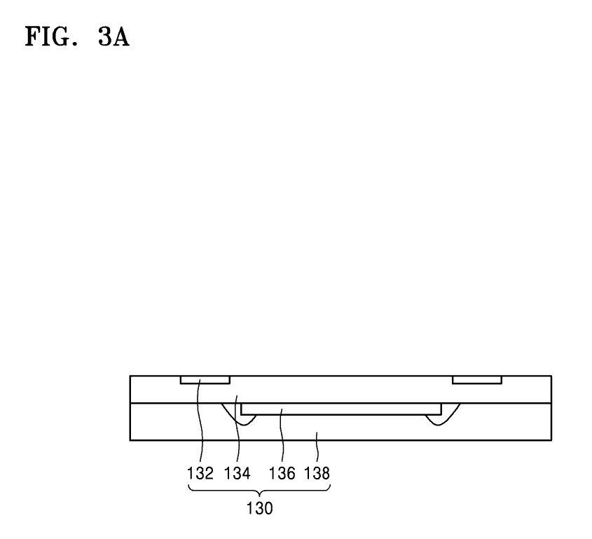

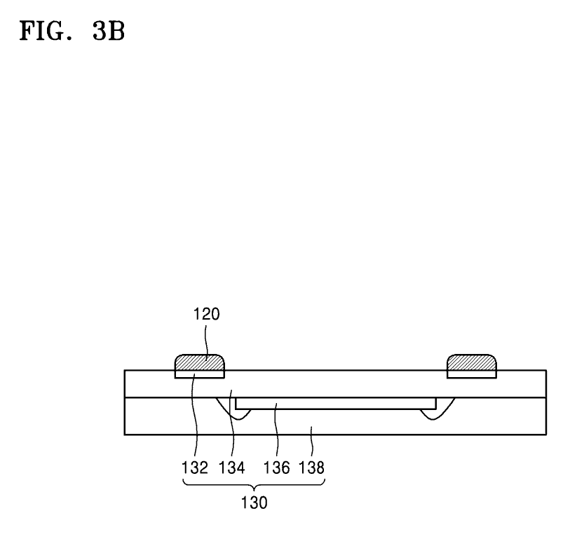

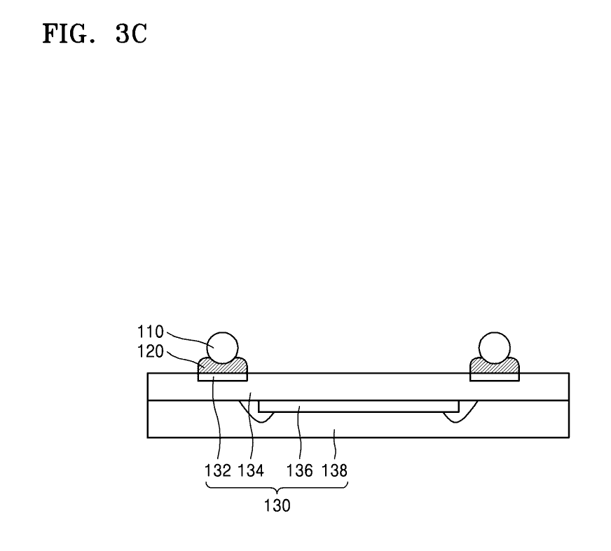

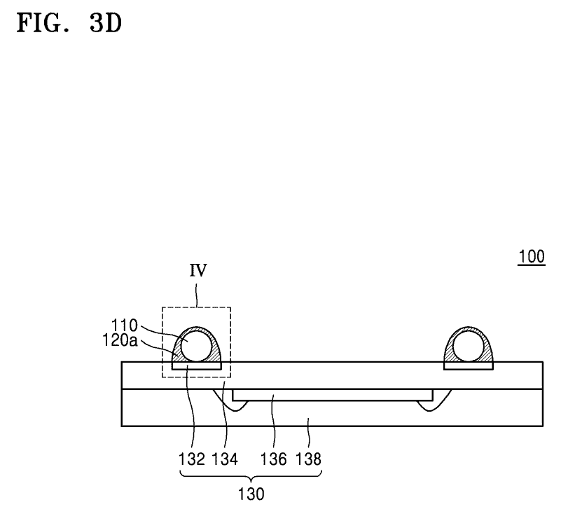

FIG. 2 is a flowchart to explain a method of fabricating a semiconductor package 100 according to an embodiment. FIGS. 3A to 3D are side cross-sectional views to explain a method of fabricating a semiconductor package 100 according to an embodiment.

Referring to FIGS. 2 and 3A, a semiconductor apparatus 130 including a bump pad 132 is provided (S100). The semiconductor apparatus 130 may include a substrate 134, the bump pad 132 formed on the surface of the substrate 134, and a semiconductor chip 136 mounted on the substrate 134.

The substrate 134 may be a printed circuit board (PCB). In various embodiments, the substrate 134 may be a rigid PCB, a flexible PCB, a tape substrate, or a rigid-flexible PCB.

When the substrate 134 is a PCB, the substrate 134 may include a core board with a first resin layer and a second resin layer respectively disposed on top and bottom surfaces thereof. Each of the first resin layer and the second resin layer may have a multi-layered structure. In various embodiments, a signal layer, a ground layer, or a power source layer may be disposed among layers constituting the multi-layered structure, and the signal layer, the ground layer, and the power source layer may form an interconnection pattern. In various embodiments, a conductive interconnection pattern may be formed on the first resin layer and/or the second resin layer. The conductive interconnection pattern may be electrically connected to the semiconductor chip 136 and the bump pad 132.

Each of the first resin layer and the second resin layer may include, for example, an epoxy resin, a urethane resin, a polyimide resin, an acryl resin, or a polyolefin resin.

The bump pad 132 may be a conductive pad, for example, a metal pad. In various embodiments, the bump pad 132 may be a copper (Cu) pad, a nickel (Ni) pad, or a nickel-plated aluminum (Al) pad. However, the bump pad 132 is not limited thereto.

The semiconductor chip 136 may be a semiconductor substrate. In various embodiments, the semiconductor substrate may be a silicon (Si) substrate. In various embodiments, the semiconductor substrate may include a semiconductor element, such as germanium (Ge), or a compound semiconductor, such as silicon carbide (SiC), gallium arsenide (GaAs), indium arsenide (InAs), and indium phosphide (InP). In various embodiments, the semiconductor substrate may have a SOI (silicon on insulator) structure. In various embodiments, the semiconductor substrate may include a buried oxide (BOX) layer.

The semiconductor substrate may have an active surface to which various semiconductor devices may be provided. The semiconductor devices may include a memory device, a core circuit device, a peripheral circuit device, a logic circuit device, or a control circuit device. Examples of the memory device include a volatile semiconductor memory device, such as DRAM or SRAM, or a non-volatile memory device, such as a flash memory, a phase-change RAM (PRAM), a resistive RAM (RRAM), a ferroelectric RAM (FeRAM), a magnetic RAM (MRAM), EPROM, EEPROM, or Flash EEPROM. Optionally, an image sensor, such as system LSI (large-scale integration) or CIS (CMOS imaging sensor), a micro-electro-mechanical system (MEMS), an active device, or an passive device may be provided to the active surface of the semiconductor substrate.

Optionally, the semiconductor apparatus 130 may further include an encapsulant 138 sealing the semiconductor chip 136. In various embodiments, the encapsulant 138 may include an epoxy molding compound.

Referring to FIGS. 2 and 3B, a solder paste 120 may be dotted on the bump pad 132 (S200).

The solder paste 120 may include a mixture including conductive metal powder and flux in a liquid state.

In various embodiments, the conductive metal powder used to prepare the solder paste 120 may include at least one selected from tin (Sn), gold (Au), silver (Ag), platinum (Pt), copper (Cu), bismuth (Bi), palladium (Pd), chromium (Cr), calcium (Ca), nickel (Ni), germanium (Ge), zinc (Zn), manganese (Mn), cobalt (Co), tungsten (W), antimony (Sb), lead (Pb), and an alloy thereof. In various embodiments, the solder paste 120 may include a lead (Pb)-containing solder alloy, for example, a Sn—Pb based alloy, a Sn—Pb—Ag based alloy, or a lead-free solder alloy, such as, Sn—Ag based alloy, a Sn—Bi based alloy, a Sn—Zn based alloy, a Sn—Sb based alloy, or a Sn—Ag—Cu alloy. The solder paste 120 may include Sn in an amount of at least 50%, at least 60%, or at least 90%, based on the total weight of metal. When the conductive metal powder includes two or more metal components, an alloy thereof may be used. When the conductive metal powder is prepared by using an alloy, the metal powder may not substantially include an organic material.

The flux may be a flux prepared by mixing a solvent, a rosin, a thixotropic agent, and an activator.

The solvent used to prepare the flux may be, for example, an organic solvent having a boiling point of 180° C. or higher. Examples of such a solvent include diethyleneglycolmonohexylether, diethyleneglycolmonobutylether, diethyleneglycolmonobutyletheracetate, tetraethyleneglycol, 2-ethyl-1,3-hexanediol, and α-terpineol.

In various embodiments, the rosin may be selected from a gum rosin, a water-added rosin, a polymerization rosin, and an ester rosin.

In various embodiments, the thixotropic agent may be selected from hydrogenated castor oil, fatty acid amide, natural oil, synthetic oil, N,N′-ethylene bis-12-hydroxy stearylamide, 12-hydroxystearic acid, 1,2,3,4-di-benzylidene-D-sorbitol, and derivatives thereof.

In various embodiments, the activator may be amine salt of hydrohalic acid. Examples thereof include amine salt of hydrochloride or hydrobromide, such as triethanolamine, diphenylguanidine, ethanolamine, butylamine, aminopropanol, polyoxyethylenoleylamine, polyoxyethylenelaureamine, polyoxyethylenestearylamine, diethylamine, triethylamine, methoxypropylamine, dimethylaminopropylamine, dibutylaminopropylamine, ethylhexylamine, ethoxypropylamine, ethylhexyloxypropylamine, bispropylamine, isopropylamine, diisopropylamine, piperidine, 2,6-dimethylpiperidine, aniline, methylamine, ethylamine, 3-amino-1-propene, dimethylhexylamine, or cyclohexylamine.

However, the solvent, the rosin, the thixotropic agent, and the activator are not limited to these materials listed above.

The flux may be prepared by mixing the solvent, the rosin, the thixotropic agent, and the activator at a certain ratio. Based on the total weight of 100 wt % of the flux, the amount of the solvent may be, for example, in a range of about 30 wt % to about 60 wt %, the amount of thixotropic agent may be, for example, in a range of about 1 wt % to about 10 wt %, and the amount of the activator may be, for example, in a range of about 0.1 wt % to about 10 wt %.

When the amount of the solvent is too small, the viscosity of the flux may be too high and accordingly, the viscosity of a solder paste including the solvent may also be high, leading to a decrease in printing properties including a filling property of solder and non-uniform coating. When the amount of the solvent is too great, the viscosity of the flux may be too low and accordingly, the viscosity of a solder paste including the solvent may also be low, leading to precipitation and separation of solder powder from the flux.

When the amount of the thixotropic agent is too small, the viscosity of the solder paste is too low, leading to precipitation and separation of the solder powder from the flux. When the amount of the thixotropic agent is too great, the viscosity of the solder paste is too high, leading to a decrease in printing properties including a filling property of solder and non-uniform coating.

In various embodiments, when the ratio of the activator to the other constituting components is too low, solder powder may not be melted and accordingly, a sufficient bonding force may not be obtained. When the ratio of the activator to the other constituting components is too high, the activator may be more likely to react with solder powder during storage, leading to a decrease in stability of solder paste during storage.

The flux may further include a viscosity stabilizer. Examples of the viscosity stabilizer include polyphenols, a phosphoric acid-based compound, a sulfur-based compound, a tocopherol, a tocopherol derivative, an ascorbic acid, and an ascorbic acid derivative, all of which are soluble in the solvent. When the amount of the viscosity stabilizer is too great, it may decrease the solubility of the solder powder. In various embodiments, the amount of the viscosity stabilizer may be about 10 wt % or less based on the weight of the flux.

In preparing solder paste, the amount of the flux may be controlled to be in a range of about 5 wt % to about 30 wt % based on 100 wt % of the solder paste after the preparation. When the amount of the flux is too small, paste may not be obtained due to the lack of the flux, and when the amount of the flux is too great, the flux content ratio in the solder paste is too high and accordingly, the metal content ratio may be too low, leading to difficulty in forming a solder bump having a desired size when solder is melted.

A dotting amount of the solder paste 120 may depend on the viscosity of the solder paste 120, the size of the bump pad 132, and the size of a reverse-reflow core to be disposed on the solder paste 120.

Referring to FIGS. 2, and 3C, the reverse-reflow core 110 may be disposed on the solder paste 120 (S300).

The reverse-reflow core 110 may be the same as the reverse-reflow core which has been described in connection with FIG. 1. A diameter of the reverse-reflow core 110 may be, for example, in a range of in a range of about 20 μm to about 300 μm. However, the diameter of the reverse-reflow core 110 is not limited thereto. Since the reverse-reflow core 110 has been described above in connection with FIG. 1, redundant descriptions thereabout will be omitted herein.

Referring to FIGS. 2 and 3D, to form a solder layer 120a on the reverse-reflow core 110, the solder paste 120 may be subjected to a reflow process (S400).

When the temperature of the solder paste 120 is raised, the solder paste 120 may be melted, coating the surface of the reverse-reflow core 110. For example, the solder paste 120 may be melted, moving along a side wall of the reverse-reflow core 110, and ultimately completely covering the surface of the reverse-reflow core 110.

Although the solder paste 120 is located under the reverse-reflow core 110, melted solder paste may move in a direction opposite to the direction of gravity and may be elevated along the surface of the reverse-reflow core 110. Here, since the viscosity of the melted solder paste 120 may be considerably too decreased, the reverse-reflow core 110 may be moved closer to the substrate 134 than a position initially disposed on the solder paste 120 which is not melted. Without wishing to be limited to a particular theory, such a movement of the reverse-reflow core 110, a surface tension of the reverse-reflow core 110, and affinity between the second metal layer constituting the reverse-reflow core 110 and the solder paste 120 may contribute to the elevation of the solder paste 120 against the gravity.

The reflow process may be performed at a temperature of about 200° C. to about 300° C., for example, about 230° C. to about 260° C. The reflow process may be performed for about 20 seconds to about 100 seconds, or about 30 seconds to about 80 seconds.

As a result, a semiconductor interconnect including the reverse-reflow core 110 and the solder layer 120a may be provided on the bump pad 132 provided to the substrate 134.

In general, a solder paste is formed by using an alloy instead of plating. Accordingly, compared to a solder formed by plating, the solder paste may not include organic impurities at all, or if any, in substantially small amounts. In other words, before used for packaging, a solder ball (copper core solder ball, CCSB) in the art using a copper core is prepared by forming a solder layer surrounding a copper core by plating. Accordingly, the solder layer may contain impurities that may be introduced thereto during the plating.

However, in embodiments, a solder paste is dotted on a bump pad and then, a core is disposed on the solder paste, followed by being subjected to a reflow process. Herein, the solder paste is prepared by using an alloy instead of plating, and accordingly, the solder paste may not include unnecessary organic impurities at all, or if any, in substantially small amounts.

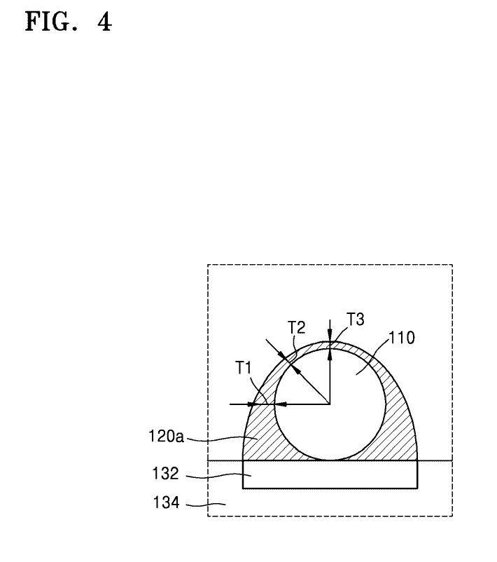

FIG. 4 shows an enlarged view of portion IV of FIG. 3.

Referring to FIG. 4, the thickness of a portion of the solder layer 120a on the surface of the reverse-reflow core 110 may vary depending on where the portion of the solder layer 120a is located. In various embodiments, a thickness T1 of a portion of the solder layer 120a corresponding to a line extending parallel to the substrate 134 from the center of the reverse-reflow core 110 may be greater than thicknesses T2 and T3 of portions of the solder layer 120a corresponding to lines extending upwards from the center of the reverse-reflow core 110.

Regarding the solder layer 120a of the reverse-reflow core 110, the thickness T3 of the portion of the solder layer 120a corresponding to the line extending perpendicular to the substrate 134 from the center of the reverse-reflow core 110 may be the smallest than those of the remaining portions of the solder layer 120a.

In this order from the thickness T3 corresponding to the line extending parallel to the substrate 134 through the thickness T1, the thickness of the solder layer 120a may gradually increase.

The reverse-reflow core 110 illustrated in FIG. 4 directly contacts the bump pad 132. However, in various embodiments, the solder layer 120a may be disposed between the reverse-reflow core 110 and the bump pad 132.

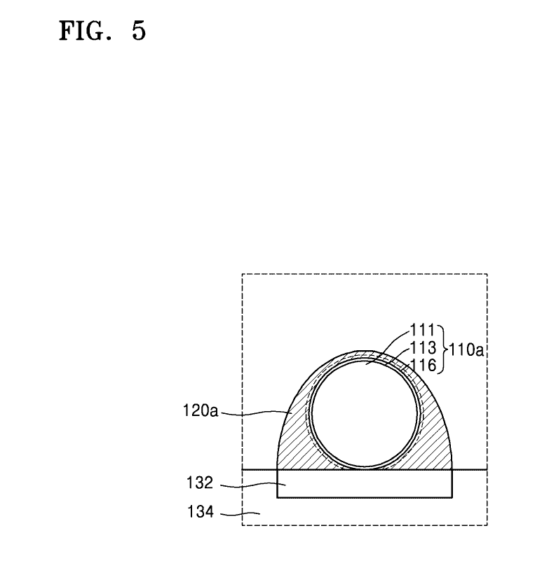

FIG. 5 shows a conceptual view of a semiconductor interconnect including a reverse-reflow core 111 and the solder layer 120a according to an embodiment.

Referring to FIG. 5, compared to the reverse-reflow core 110 illustrated in FIG. 1, the core 111 and the first metal layer 113 may be the same as described above. The second metal layer 115 illustrated in FIG. 1 may form an alloy and/or an intermetallic compound (IMC) with the solder layer 120a in preparing the solder layer 120a.

The second metal layer 115 of the reverse-reflow core 110 illustrated in FIG. 1 may have a small thickness of about 0.1 μm to about 0.3 μm. Accordingly, the second metal layer 115 may be completely dissolved to solder layer during reflow process, thereby forming an alloy and/or an IMC with the solder layer 120a. In some embodiments, only a portion of the second metal layer 115 may form an alloy and/or an IMC with the solder layer 120a. In the embodiment illustrated in FIG. 5, the second metal layer 115 may completely form an alloy and/or an intermetallic compound together with the solder layer 120a. However, the second metal layer 115 is not limited thereto.

In various embodiments, the first metal layer 113 may partially or completely form an intermetallic compound together with the solder layer 120a, thereby forming an interfacial layer 116. In various embodiments, a portion of the first metal layer 113 may form an intermetallic compound with the solder layer 120a. In various embodiments, the first metal layer 113 may completely form an intermetallic compound with the solder layer 120a. The solder layer 120a may be a tin (Sn)-based solder. In various embodiments, the intermetallic compound may include a component constituting the core 111. When the first metal layer 113 completely forms an intermetallic compound with the solder layer 120a, the first metal layer 113 illustrated FIG. 5 may not exist, and instead, the interfacial layer 116 may be directly present on the surface of the core 111.

The intermetallic compound may include, for example, at least one selected from NiCu₃Sn₄, (Cu,Ni)₆Sn₅, and Ni₃Sn₄. However, the intermetallic compound is not limited thereto, and may vary according to materials constituting the core 111, the first metal layer 113, and the solder layer 120a.

The interfacial layer 116 may include an intermetallic compound that contains a component derived from the first metal layer 113 and a component derived from the solder layer 120a. Furthermore, the interfacial layer 116 may include an alloy that contains a component derived from the second metal layer 115 and the component derived from the solder layer 120a.

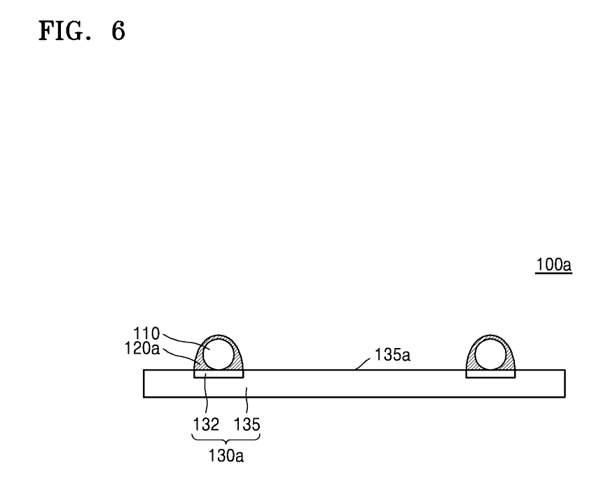

FIG. 6 shows a cross-sectional view of a semiconductor package 100a according to an embodiment.

Referring to FIG. 6, a semiconductor substrate 135 with a bump pad 132 disposed thereon is provided. The semiconductor substrate 135 may have an active surface 135a and an inactive surface 135b.

In various embodiments, the semiconductor substrate 135 may be a silicon (Si) substrate. In various embodiments, the semiconductor substrate 135 may include a semiconductor element, such as Ge (germanium), or a compound semiconductor, such as SiC (silicon carbide), GaAs (gallium arsenide), InAs (indium arsenide), and InP (indium phosphide). In various embodiments, the semiconductor substrate 135 may have a SOI (silicon on insulator) structure. In various embodiments, the semiconductor substrate 135 may include a buried oxide (BOX) layer. In various embodiments, the semiconductor substrate 135 may include a conductive region, for example, an impurity-doped well or an impurity-doped structure. In various embodiments, the semiconductor substrate 135 may have various device-isolating structures, including a shallow trench isolation (STI) structure.

Various semiconductor devices may be provided on the active surface 135a of the semiconductor substrate 135. The semiconductor devices may include a memory device, a core circuit device, a peripheral circuit device, a logic circuit device, or a control circuit device. Examples of the memory device include a volatile semiconductor memory device, such as DRAM or SRAM, or a non-volatile memory device, such as a flash memory, a phase-change RAM (PRAM), a resistive RAM (RRAM), a ferroelectric RAM (FeRAM), a magnetic RAM (MRAM), EPROM, EEPROM, or Flash EEPROM. Optionally, an image sensor, such as system LSI (large-scale integration) or CIS (CMOS imaging sensor), a micro-electro-mechanical system (MEMS), an active device, or an passive device may be provided on the active surface 135a of the semiconductor substrate 135.

An interconnection layer may be provided to semiconductor devices on the active surface 135a of the semiconductor substrate 135. The interconnection layer may include an interconnection pattern and an insulating layer. The interconnection pattern may be electrically connected to the bump pad 132 which is an electrode terminal.

The reverse-reflow core 110 and the solder layer 120a, which constitute the semiconductor interconnect, have been described in detail in connection with FIGS. 1 to 5. Accordingly, redundant descriptions thereabout will be omitted herein.

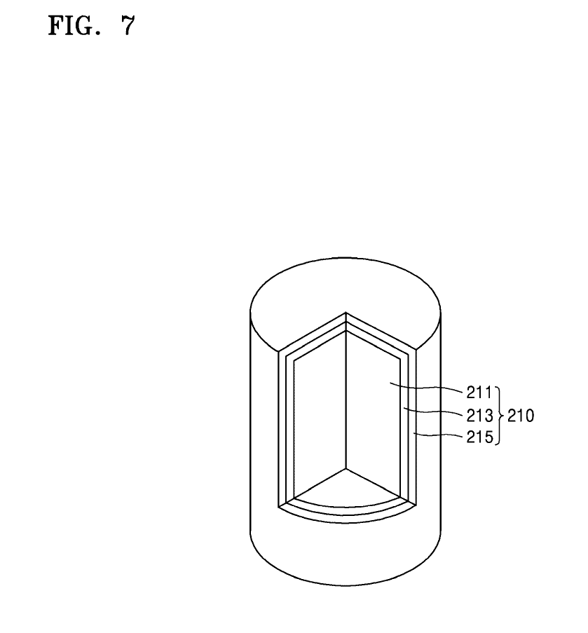

FIG. 7 is a cross-sectional perspective view of a reverse-reflow core 210 according to an embodiment.

Referring to FIG. 7, the reverse-reflow core 210 may include a core 211, a first metal layer 213 coating the core 211, and a second metal layer 215 coating the first metal layer 213.

The reverse-reflow core 210 may have a diameter of about 20 μm to about 300 μm in a horizontal direction thereof. A height of the reverse-reflow core 210 may be in a range of about 50 μm to about 1000 μm. However, measurements of the reverse-reflow core 210 are not limited thereto.

Referring to FIG. 7, the core 211 has a cylindrical shape, the first metal layer 213 having a substantially uniform thickness may be formed on the core 211, and the second metal layer 215 having a substantially uniform thickness may be formed on the first metal layer 213.

Materials constituting the core 211, the first metal layer 213, and the second metal layer 215 have been described in detail in connection with FIG. 1. Accordingly, redundant explanations thereabout will be omitted herein. The thicknesses of the first metal layer 213 and the second metal layer 215 also have been described in detail in connection with FIG. 1. Accordingly, redundant explanations thereabout will be omitted therein.

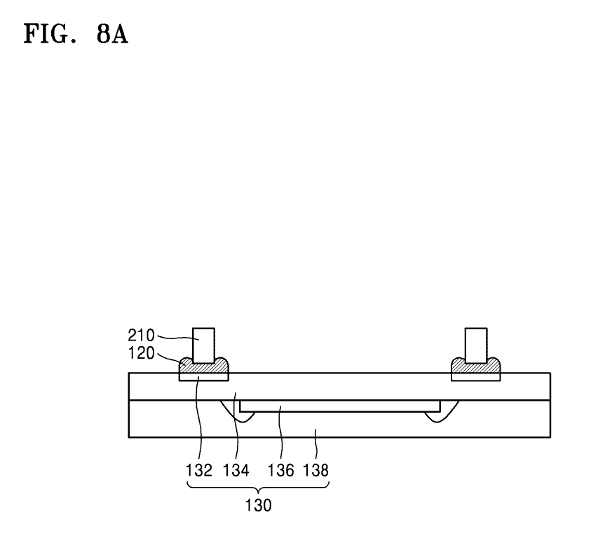

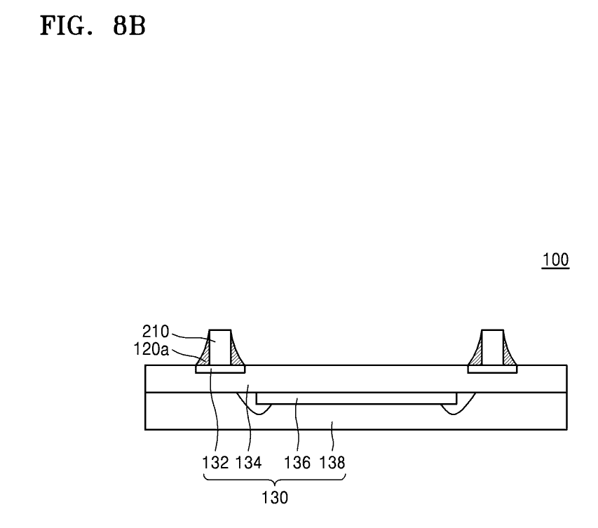

FIGS. 8A and 8B show side cross-sectional views of a semiconductor package including the reverse-reflow core 210 illustrated in FIG. 7 to explain a method of fabricating a semiconductor package according to an embodiment. The side cross-sectional views of FIGS. 8A and 8B are used herein to explain processes following the processes that have been explained in connection with FIGS. 3A and 3B.

Referring to FIG. 8A, the reverse-reflow core 210 may be disposed on the solder paste 120. Since the solder paste 120 is in a paste state, the solder paste 120 has fluidity. Accordingly, it is possible to dispose the reverse-reflow core 210 having a cylindrical shape on the solder paste 120, as illustrated in FIG. 8A.

The reverse-reflow core 210 has been described in detail in connection with FIG. 7. Accordingly, redundant explanations thereabout will be omitted herein.

Referring to FIG. 8B, the solder paste 120 may be subjected to a reflow process to form the solder layer 120a on the surface of the reverse-reflow core 210.

When the temperature of the solder paste 120 illustrated in FIG. 8A is raised, the solder paste 120 is melted to coat a portion of the reverse-reflow core 210. For example, the solder paste 120 is melted, and then, elevated along a side wall of the reverse-reflow core 210 as explained in connection with FIG. 3D to cover at least a portion of the reverse-reflow core 210.

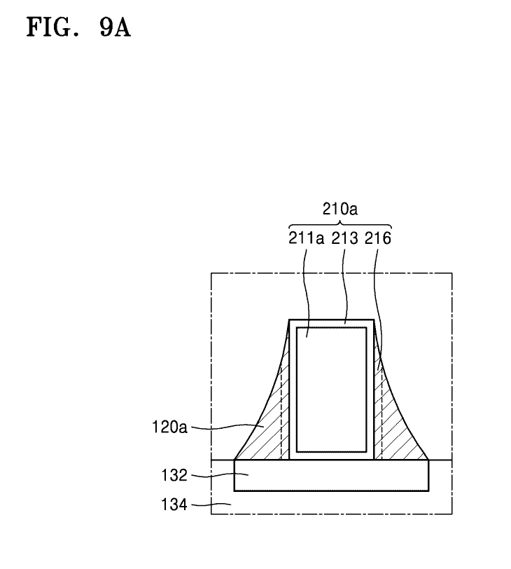

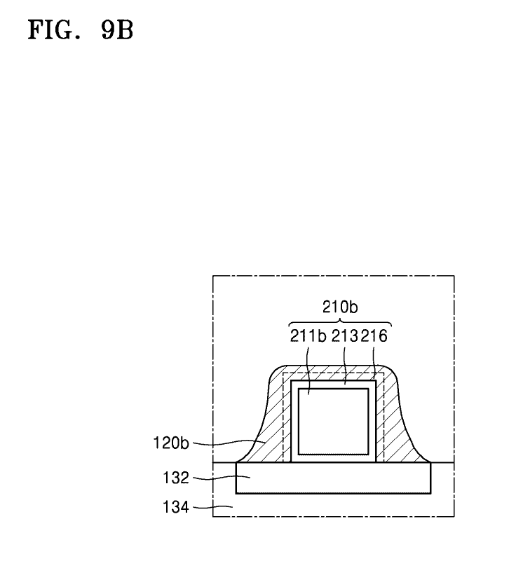

When an aspect ratio (a ratio of height to width) of the reverse-reflow core 210 is high, the solder paste 120 may not reach a top end of the reverse-reflow core 210. In the case of the reverse-reflow core 210 illustrated in FIG. 7, the solder paste 120 may show more various behaviors than in the case of the reverse-reflow core 110 illustrated in FIG. 1. Such behaviors will be described in detail in connection with FIGS. 9A and 9B.

Referring to FIG. 8B, when the viscosity of the solder paste 120 is reduced due to the reflow, the reverse-reflow core 210 may move more toward the substrate 134 than as illustrated in FIG. 8A because of the gravity. Conditions for the reflow process have been described in detail in connection with FIG. 3D. Accordingly, redundant explanations thereabout will be omitted herein.

As a result, a semiconductor interconnect including the reverse-reflow core 210 and the solder layer 120a is provided on the bump pad 132 of the substrate 134.

FIGS. 9A and 9B show side cross-sectional views of various examples of the semiconductor interconnect including the reverse-reflow core 210 and the solder layer 120a.

Referring to FIG. 9A, the solder layer 120a may be formed along the side wall of a reverse-reflow core 210a, and a thickness of a portion of the solder layer 120a may vary depending on where the portion of the solder layer 120a is located. For example, the thickness of the portion of the solder layer 120a may be decreased as the portion of the solder layer 120a moves upwards along the side wall of the reverse-reflow core 210a.

The solder layer 120a may not completely coat the reverse-reflow core 210a. This partial coating may be due to a high aspect ratio or height of the reverse-reflow core 210a. In various embodiments, the solder layer 120a that is formed by the reflow process may be elevated along the side wall of the reverse-reflow core 210a only up to a certain level. The elevation level may depend on, for example, the composition and amount of the solder layer 120a, a reflow temperature, or measurements of the reverse-reflow core 210a.

In this regard, the second metal layer (215, see FIG. 7) of the reverse-reflow core 210a may react with the solder layer 120a to form an intermetallic compound layer 216. As a result, after the reflow process, the reverse-reflow core 210a may include a core 211a and the first metal layer 213.

Although the reverse-reflow core 210a illustrated in FIG. 9A directly contacts the bump pad 132, in some cases, at least a portion of the solder layer 120a may be disposed between the reverse-reflow core 210a and the bump pad 132.

When, as illustrated in FIG. 9A, the solder layer 120a does not coat a top surface of the reverse-reflow core 210a, a terminal (for example, a bump pad) of another substrate (not shown) to be electrically connected to the substrate 134 may further include a connecting element, for example, solder paste.

A reverse-reflow core 210b illustrated in FIG. 9B is different from the reverse-reflow core 210a illustrated in FIG. 9A, in that a solder layer 120b coats up to on a top surface of the solder layer 120b.

As described above, by controlling the composition and amount of the solder paste 120b, a reflow temperature, or measurements of the reverse-reflow core 210b, it is possible to coat the top surface of the reverse-reflow core 210b by the solder layer 120b. In various embodiments, when a reflow temperature is high, the viscosity of the solder paste 120b is decreased and wettability thereof is improved, leading to a high likelihood that the solder paste 120b coats up to the top surface the reverse-reflow core 210b. In various embodiments, when the amount of the solder paste 120b is great and the viscosity thereof is low, the solder paste 120b may highly likely coat up to the top surface the reverse-reflow core 210b. In various embodiments, when measurements of the reverse-reflow core 210b, that is, the diameter and/or height of the reverse-reflow core 210b are small, the solder paste 120b may highly likely coat up to the top surface the reverse-reflow core 210b.

As illustrated in FIG. 9B, the intermetallic compound layer 216 may be formed on an interface between the solder layer 120b and the reverse-reflow core 210b. The intermetallic compound layer 216 may be formed by reacting the second metal layer (215, see FIG. 7) with the solder layer 120b. As a result, after the reflow process, the reverse-reflow core 210b may include a core 211b and the first metal layer 213.

Hereinafter, the structure and effects of the present disclosure will be described in detail with reference to Experimental Examples and Comparative Examples. However, these examples are provided herein for illustrative purpose only, and do not limit the scope of the present disclosure.

### EXPERIMENTAL EXAMPLE 1

A copper core having a diameter of 184 μm was prepared, and then, a degreasing process and a pickling process were performed thereon to remove an organic material and an oxide film being present on the surface of the copper core therefrom.

### EXPERIMENTAL EXAMPLES 2 TO 7

Copper cores each having a diameter of 180 μm were prepared, and then, a degreasing process and a pickling process were performed thereon to remove an organic material and an oxide film being present on the surface of each of the copper cores therefrom. Then, an Ni layer having a thickness of 2 μm was formed thereon by using a sulfonic acid-based Ni plating solution at a current density of about 0.5 to about 1 ASD (amperes per square decimeter).

Then, in the case of Experimental Examples 3 to 6, as shown in Table 1, a gold (Au) or palladium (Pd) layer was formed thereon with an appropriate thickness. In the case of Experimental Example 7, as shown in Table 1, a plating layer including (Sn)-(3% Ag)-(0.5% Cu)(hereinafter referred to as SAC) having a thickness of 18 μm was formed on the copper core.

The samples of Experimental Example 1 to 7 were placed for aging in the air atmosphere in an oven at a temperature of 120° C. for 48 hours, and then, the illuminance of the surface of each of the samples was measured. The illuminance was measured by using a MINOLTA CR-400 chroma meter.

In the case of Experimental Examples 1 and 7, the illuminance was reduced greatly, and in the case of Experimental Example 2, the illuminance was slightly reduced. These results show that in the case of Experimental Examples 3 to 6, due to the surface treatment using gold (Au) or palladium (Pd), oxidizing the surfaces of the copper cores was suppressed, and in the case of Experimental Examples 1, 2, and 7, the oxidizing occurred considerably or slightly.

In proportion to the oxidation degree, it is seen that the surfaces of the samples was discolored. In other words, in the case of Experimental Examples 3 to 6, the color of the surfaces of the samples was not changed before and after the aging, and in the case of Experimental Examples 1, 2, and 7, the color of the surfaces of the samples was slightly or considerably changed before and after the aging.

TABLE 1

| | | Ni | SAC | | Total | | | |
|---|---|---|---|---|---|---|---|---|
| | Diameter of | plating | plating | Surface | Diameter | Initial | Illuminance | |
| | Core (μm) | (μm) | (μm) | Treatment | (μm) | Illuminance | after aging | discoloration |
| Experimental | 184 | — | — | — | 184 | 75 | 32 | ⊚ |
| Example 1 | | | | | | | | |
| Experimental | 180 | 2 | — | — | 184 | 52 | 50 | Δ |
| Example 2 | | | | | | | | |
| Experimental | 180 | 2 | — | Au 0.1 μm | 184 | 73 | 73 | X |
| Example 3 | | | | | | | | |
| Experimental | 180 | 2 | — | Au 0.3 μm | 184 | 74 | 74 | X |
| Example 4 | | | | | | | | |
| Experimental | 180 | 2 | — | Pd 0.1 μm | 184 | 73 | 73 | X |
| Example 5 | | | | | | | | |
| Experimental | 180 | 2 | — | Pd 0.3 μm | 184 | 73 | 73 | X |
| Example 6 | | | | | | | | |
| Experimental | 180 | 2 | 18 | — | 220 | 74 | 63 | ◯ |
| Example 7 | | | | | | | | |

### EXPERIMENTAL EXAMPLES 8 TO 13

Wettability of the pre-aging samples of Experimental Examples 1 to 6 with respect to solder paste was evaluated. To do this, a metal pad of Cu-OSP (organic solderability preservative) PCB was coated uniformly with SAC305 paste by using a 100 μm-thick mask that had been patterned to have a diameter of 200 μm, and then, the samples of Experimental Examples 1 to 6 were disposed thereon. The resultant structures were subjected to a reflow process. The reflow process was performed at a temperature of 245° C. for 50 seconds.

### EXPERIMENTAL EXAMPLES 14 TO 19

Wettability of the post-aging samples of Experimental Examples 1 to 6 with respect to solder paste were evaluated in the same manner as used to evaluate the samples of Experimental Examples 8 to 13.

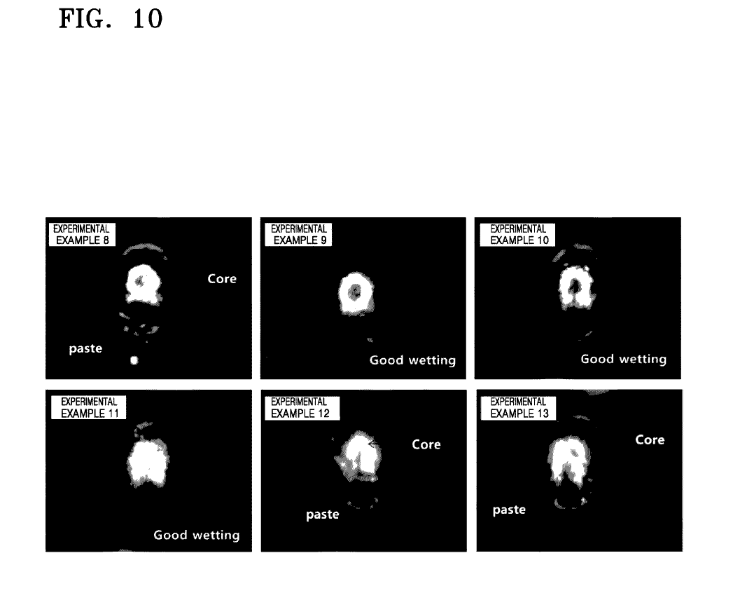

FIG. 10 shows images of the results of Experimental Example 8 to Experimental Example 13. Referring to FIG. 10, it is seen that a portion of each of the samples of Experimental Examples 8, 12, and 13 is exposed. From these images, it is seen that the wettability of the samples with respect to melted solder are not fair during the reflow process.

In the case of Experimental Examples 9, 10, and 11, the samples are not exposed and solder forms a solder layer completely covering the samples. From these results, it is seen that the wettability between solder and nickel or solder and gold are fair.

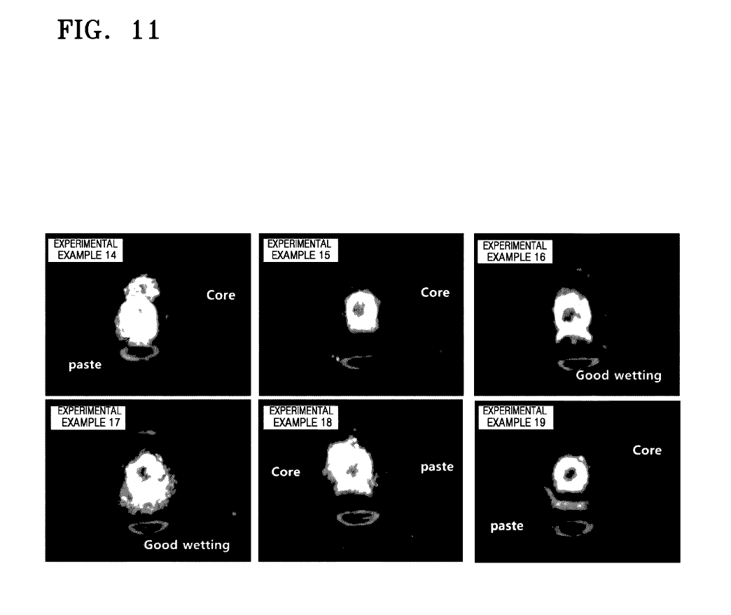

FIG. 11 shows images of the results of Experimental Example 14 to Experimental Example 19. Referring to FIG. 11, in the case of Experimental Example 15, it is seen that the sample is considerably exposed. In comparison, as described above, in the case of Experimental Example 9 in which aging was not performed, a solder layer was completely coated on the copper core. From these results, it is seen that wettability between nickel and solder deteriorated due to the oxidation during aging.

However, in the case of Experimental Examples 16 and 17 in which gold (Au) was coated, the solder layer was still completely coated on the copper cores. From this result, it is seen that the Au coating layer has a strong resistance to oxidizing.

In the case of Experimental Examples 18 and 19 in which palladium (Pd) was coated, before and after the aging, illuminance did not change, but, similar to that before the aging, the wetting characteristics between melted solder and palladium (Pd) were not fair enough.

From these results, it is seen that when gold (Au) is used to form a second metal layer, even when stored for a long period of time, the copper cores show stable wettability with respect to solder.

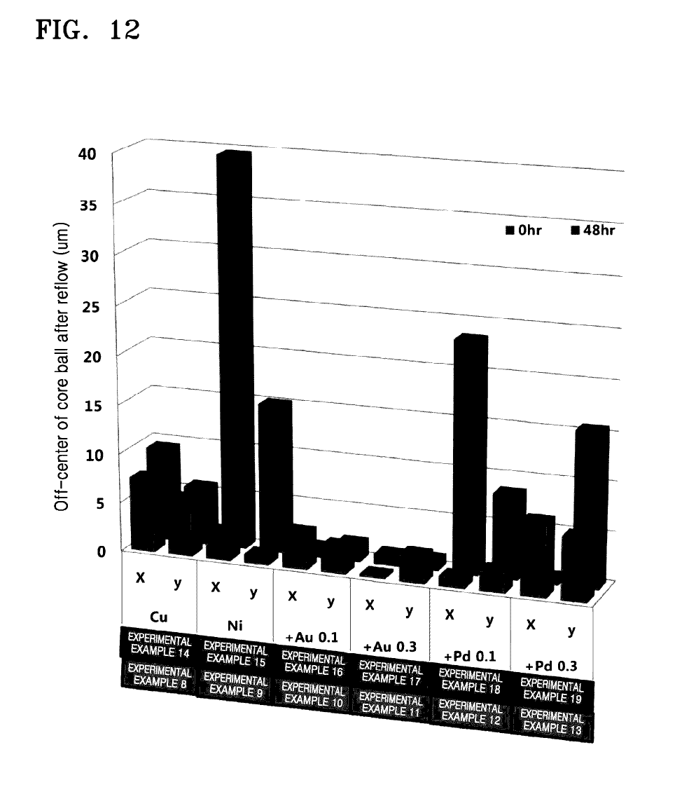

FIG. 12 shows a graph of off-center displacement of the samples of Experimental Examples 8 to 19 in a horizontal direction (X direction) and a vertical direction (Y direction), caused by reflow. The location of the copper cores before and after reflow was identified by image analysis to measure the off-center displacement of the copper cores.

Referring to FIG. 12, in the case of Experimental Examples 15, 18, and 19, the copper cores were largely separated from their surrounding structures. In the case of Experimental Examples 8 and 14, it is seen that the copper coppers are still moved in the horizontal and vertical directions each by about 10 μm during reflow although the displacement is smaller than those of Experimental Examples 15, 18, and 19.

In the case of Experimental Examples 10, 11, 16, and 17, however, the samples were moved by an extremely small distance, for example, about 5 μm or less.

Accordingly, when gold (Au) is used to form a second metal layer, the copper core hardly moves during reflow. Thus, excellent centering characteristics may be obtained.

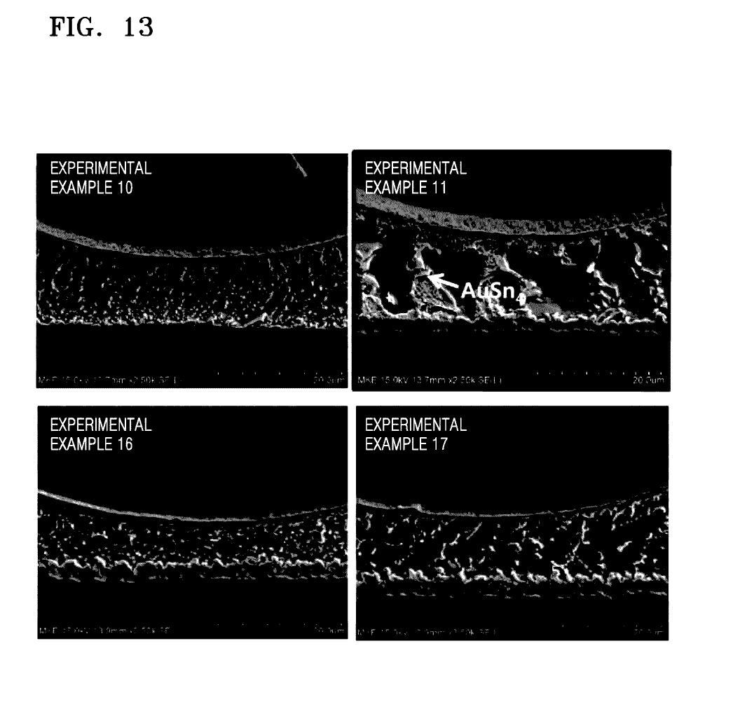

FIG. 13 shows images of an interfacial compound between the samples of Experimental Examples 10, 11, 16, and 17 and a solder, the copper cores each being coated with gold.

Referring to FIG. 13, in the case of Experimental Example 11, in which aging was not performed, an intermetallic compound of AuSn₄ was observed to be formed. Since the AuSn₄ intermetallic compound has high brittleness, the thickness of a second metal layer may be kept to be 0.3 μm or less.

### <Bonding Strength Measurements>

Bonding strength of the samples of Experimental Examples 7 to 13 was measured as follows.

Force was horizontally applied to the samples of Experimental Examples 8 to 13 at heights 10 μm and 80 μm from the PCB. The intensity of force when breaking begins is referred to as a bonding strength.

The sample of Experimental Example 7 was bonded to a PCB substrate having corresponding bump pad, and then, bonding strength thereof was measured in the same manner as used in connection with the samples of Experimental Examples 8 to 13.

In each case, when force is applied in the PCB side (i.e., at a height of 10 μm), bonding characteristics of an interface between a bump pad and a solder are a major determining factor, and when force is applied in the core side (i.e., at a height of 80 μm), bonding characteristics of an interface between a reverse-reflow core and a solder are a major determining factor.

Measurement results are shown in Table 2.

TABLE 2
(unit: g_{f})

| | PCD side | core side |
|---|---|---|
| | (height of 10 μm) | (height of 80 μm) |
| Experimental | 152 | 133 |
| Example 8 | | |
| Experimental | 154 | 168 |
| Example 9 | | |
| Experimental | 211 | 236 |
| Example 10 | | |
| Experimental | 195 | 225 |
| Example 11 | | |
| Experimental | 161 | 160 |
| Example 12 | | |
| Experimental | 170 | 180 |
| Example 13 | | |
| Experimental | 155 | 160 |
| Example 7 | | |

Referring to Table 2, in the case of Experimental Examples 7 to 9 in which the copper core solder ball (CCSB) in the art was used, a bonding strength was as low as about 150 g_{f}. In the case of Experimental Examples 12 and 13 in which palladium was used for coating, the bonding strength was about 170 g_{f}.

In the case of Experimental Examples 10 and 11 in which gold (Au) was used for coating, the bonding strength was above 200 g_{f}.

As described above, a core for reverse reflow according to embodiments, a semiconductor package according to embodiments, and a method of fabricating a semiconductor package according to embodiments enable the fabrication of a semiconductor package having high bonding strength to a high degree of precision.

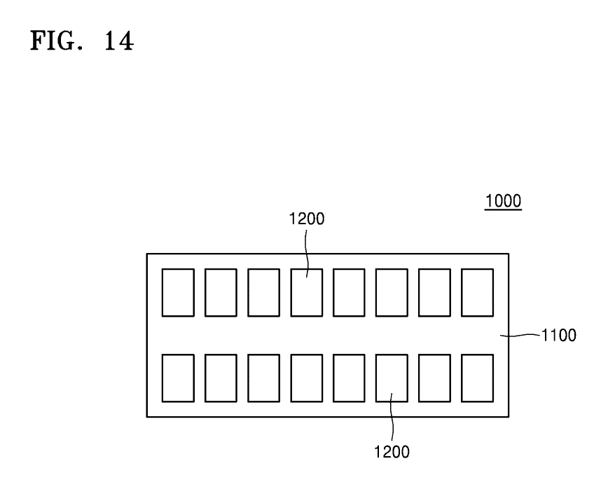

FIG. 14 is a plan view of a memory module 1000 including a semiconductor package according to an embodiment of the present disclosure.

For example, the memory module 1000 may include a printed circuit substrate 1100 and a plurality of semiconductor packages 1200.

The semiconductor packages 1200 may be or may include a semiconductor package according to embodiments. For example, the semiconductor packages 1200 may include at least one semiconductor package selected from semiconductor packages according to embodiments.

The memory module 1000 may be a single in-lined memory module (SIMM) in which the semiconductor packages 1200 are mounted on one surface of the printed circuit substrate 1100, or a dual in-lined memory module (DIMM) in which the semiconductor packages 1200 are mounted on facing surfaces of the printed circuit substrate 1100. The memory module 1000 may be a fully buffered DIMM (FBDIMM) including an advanced memory buffer (AMB) that provides external signals to the semiconductor packages 1200.

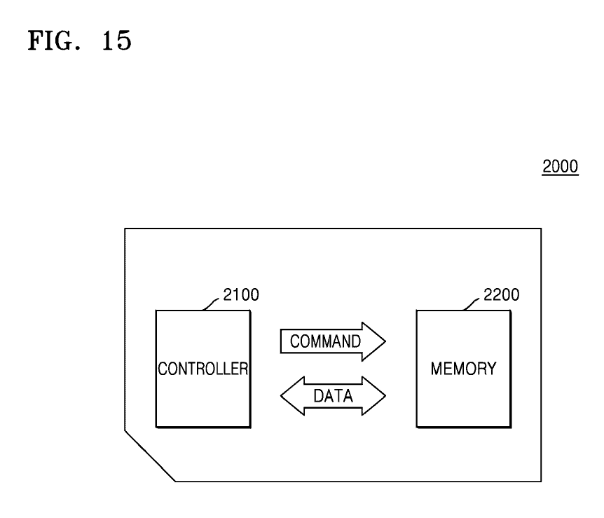

FIG. 15 is a schematic diagram of a memory card 2000 including a semiconductor package, according to an embodiment of the present disclosure.

In the memory card 2000, a controller 2100 and a memory 2200 may be disposed to exchange electric signals. For example, when the controller 2100 commands, the memory 2200 may transfer data.

The memory 2200 may include a semiconductor package according to an embodiment. In various embodiments, the memory 2200 may include at least one semiconductor package selected from the semiconductor packages according to the above-described embodiments of the present disclosure.

The memory card 2000 may configure various kinds of memory cards, for example, a memory stick card, a smart media card (SM), a secure digital card (SD), a mini-secure digital card (mini SD), and a multimedia card (MMC).

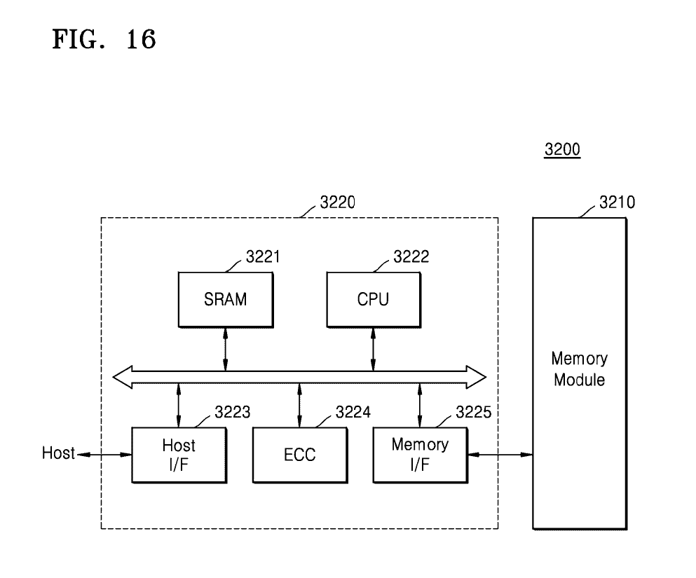

FIG. 16 is a block diagram of a memory apparatus 3200 including a semiconductor package according to an embodiment according to the present disclosure.

Referring to FIG. 16, the memory apparatus 3200 includes a memory module 3210. The memory module 3210 may include at least one of the semiconductor packages described above according to the embodiments of the present disclosure. Also, the memory module 3210 may further include a semiconductor memory device (for example, a non-volatile memory device and/or SRAM) of a different type. The memory apparatus 3200 may include a memory controller 3200 controlling data exchange between a host and the memory module 3210.

The memory controller 3220 may include a processing unit 3222 that controls overall operations of the memory apparatus 3200. Also, the memory controller 3220 may include SRAM 3221 that is used as an operating memory of the processing unit 3222. Moreover, the memory controller 3220 may further include a host interface 3223 and a memory interface 3225. The host interface 3223 may include a data exchange protocol between the memory apparatus 3200 and the host. The memory interface 3225 may connect the memory controller 3220 and the memory module 3210 to each other. Further, the memory controller 3220 may further include an error correction code (ECC) block 3224. The ECC block 3224 may detect and correct errors of the data read from the memory module 3210. Although not shown in FIG. 16, the memory apparatus 3200 may further include ROM storing code data for interfacing with the host. The memory apparatus 3200 may be configured as a solid state drive (SSD) that may replace a hard disk of a computer system.

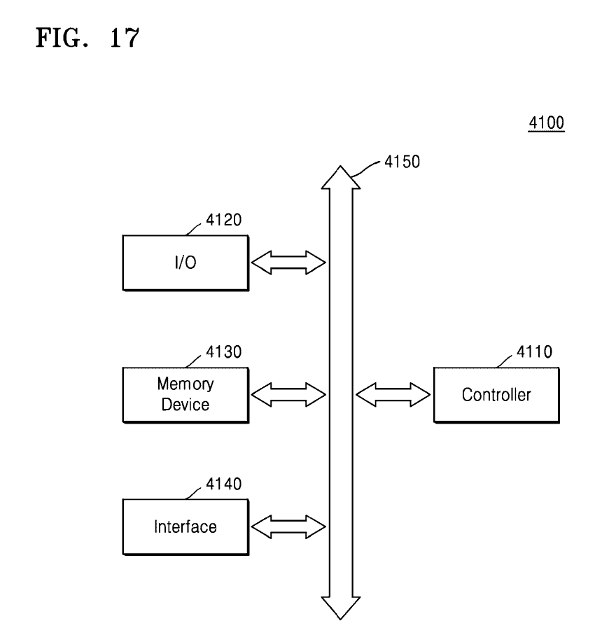

FIG. 17 is a block diagram of an electronic system 4100 including a semiconductor package, according to an embodiment of the present disclosure.

Referring to FIG. 17, the electronic system 4100 according to the present embodiment may include a controller 4110, an input/output (I/O) device 4120, a memory device 4130, an interface 4140, and a bus 4150. The controller 4110, the I/O device 4120, the memory device 4130, and/or the interface 4140 may be connected to each other via the bus 4150. The bus 4150 corresponds to a path through which data is transferred.

The controller 4110 may include at least one of a microprocessor, a digital signal processor, a microcontroller, and logic devices performing similar functions. The I/O device 4120 may include a keypad, a keyboard, and a display device. The memory device 4130 may store data and/or commands. The memory device 4130 may include at least one of the semiconductor packages described above according to the embodiments of the present disclosure. Also, the memory device 4130 may further include a semiconductor memory device of a different type (for example, a non-volatile memory device and/or SRAM). The interface 4140 may transfer data to a communication network or receive data from the communication network. The interface 4140 may be a wired or a wireless interface. For example, the interface 4140 may include an antenna or a wired/wireless transceiver. Although not shown in FIG. 17, the electronic system 4100 may further include high speed DRAM and/or SRAM as an operating memory device for improving operations of the controller 4110.

The electronic system 4100 may be applied to a personal digital assistant (PDA), a portable computer, a web tablet, a wireless phone, a mobile phone, a digital music player, a memory card, or all kinds of electronic products that may transmit and/or receive information in a wireless environment.

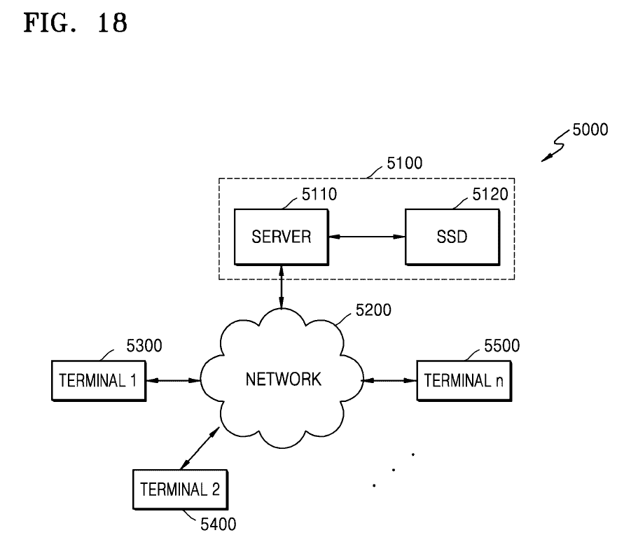

FIG. 18 is a block diagram of a network system 5000 including a server system 5100 including a semiconductor package, according to an embodiment of the present disclosure.

Referring to FIG. 18, the network system 5000 according to the present embodiment may include the server system 5100 and a plurality of terminals 5300, 5400, and 5500 that are connected to each other via a network 5200. The server system 5100 according to the present embodiment may include a server 5110 processing requests transmitted from the plurality of terminals 5300, 5400, and 5500 connected to the network 5200, and the electronic device 5120 storing data corresponding to the requests transmitted from the terminals 5300, 5400, and 5500. Here, the electronic device 5120 may be a semiconductor package according to the embodiments of the present disclosure as shown in FIGS. 4 through 6. The electronic device 5120 may be, for example, an SSD.

The electronic devices described above may be mounted in various types of packages, for example, package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat-pack (MQFP), thin quad flat-pack (TQFP), small outline integrated circuit (SOIC), shrink small outline package (SSOP), thin small outline package (TSOP), thin quad flat-pack (TQFP), system in package (SIP), multi-chip package (MCP), water-level fabricated package (WFP), and water-level processed stack package (WSP).

While the present disclosure has been particularly shown and described with reference to exemplary embodiments thereof, it will be understood that various changes in form and details may be made therein without departing from the spirit and scope of the following claims.

What is claimed is:

1. A reverse-reflow core, the reverse-reflow core comprising:
a core;
a first metal layer that coats the core; and
a second metal layer that coats the first metal layer, wherein the first metal layer comprises nickel (Ni) or cobalt (Co), the second metal layer comprises gold (Au) or platinum (Pt), and a thickness of the second metal layer is in a range of about 0.01 μm to about 0.3 μm.

2. A semiconductor package comprising:
a semiconductor apparatus comprising a bump pad; and
a bump portion bonded to the bump pad, wherein the bump portion comprises:
a core;
an intermetallic compound layer formed on the core; and
a solder layer coating the intermetallic compound layer,
wherein the thickness of a portion of the solder layer decreases as the distance between the portion of the solder layer and the bump pad increases.

3. The semiconductor package of claim 2, wherein
the solder layer coats the intermetallic compound layer in such a manner that the solder layer completely surrounds the core.

4. The semiconductor package of claim 2, wherein
the intermetallic compound of the intermetallic compound layer comprises at least one selected from NiCu₃Sn₄, (Cu,Ni)₆Sn₅, and Ni₃Sn₄.

5. The semiconductor package of claim 4, further comprising
a first metal layer between the core and the intermetallic compound layer.

6. The semiconductor package of claim 2, wherein
the semiconductor apparatus is a semiconductor chip.

7. The semiconductor package of claim 2, wherein
the semiconductor apparatus comprises a package substrate, and a semiconductor chip disposed on the package substrate, and
the bump pad is provided on the package substrate.

8. The semiconductor package of claim 2, wherein
the solder layer does not substantially comprise an organic material.

9. The semiconductor package of claim 2, wherein
the core is spherical, and
the thickness of the solder layer is monotonically decreased away from the bump pad.

10. The semiconductor package of claim 2, wherein
the core is cylindrical, and
the thickness of the solder layer gradually decreases away from the bump pad, and the solder layer does not cover at least a portion of a top surface of the core.

11. The semiconductor package of claim 2, wherein
the core is cylindrical, and
the thickness of the solder layer gradually decreases away from the bump pad, and the solder layer covers a top surface of the core.

12. A method of fabricating a semiconductor package, the method comprising:
providing a substrate with a bump pad thereon;
dotting solder paste or reflowed solder bump on the bump pad;
providing a reverse-reflow core on the solder paste or the reflowed solder bump; and
reflowing the solder paste or the solder bump to form a solder layer on the reverse-reflow core;
wherein the reverse-reflow core comprises a gold (Au) or platinum (Pt) layer as a surface thereof.

13. The method of claim 12, wherein
the gold (Au) or platinum (Pt) layer has a thickness of about 0.1 μm to about 0.3 μm.

14. The method of claim 12, wherein
the reflowing of the solder paste is performed at a temperature of about 200° C. to about 300° C.

15. The method of claim 12, wherein
the reverse-reflow core is off-centered by 5 μm or less before and after the reflowing of the solder paste.

16. The method of claim 12, wherein
in the reflowing of the solder paste, the solder paste is elevated along a surface of the reverse-reflow core in a direction opposite to a direction of gravity.

17. The method of claim 16, wherein
a thickness of the solder layer gradually decreases away from the substrate.

18. An electronic system comprising:
a controller;
an input or output unit to input or output data;
a memory unit to store the data;
an interface unit to transmit data to an external apparatus; and
a bus to connect the controller, the input/output unit, the memory unit, and the interface unit so that the controller, the input/output unit, the memory unit, and the interface unit communicate with each other,
wherein at least one of the controller and the memory unit comprises the semiconductor package of claim 2.
